(19) United States
(12) Patent Application Publication
(10) Pub. No.: US 2006/0017597 A1
(43) Pub. Date: Jan. 26, 2006

(54) Method of signal reconstruction, imaging device and computer program product

(75) Inventor: Cornelis Antonie Maria Jaspers, Hapert (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/526,866

(22) PCT Filed: Jul. 31, 2003
(86) PCT No.: PCT/IB03/03751

§ 371 Date: Mar. 4, 2005

(30) Foreign Application Priority Data
Sep. 9, 2002 (EP) 02078667.9

(51) Int. Cl. H03M 1/12

(52) U.S. Cl. 341/155

(57) ABSTRACT

A dynamic range control is of particular interest for scenes with a high contrast between dark and bright parts. Both parts may contain detailed information, although in most cases the dark part is given priority during signal reconstruction processing. In such a case the dark parts of a scene are amplified to a level that offers sufficient visible details, whereas in most prior art cases the bright parts may exceed the maximum permissible signal amplitude and will then be clipped. Such a measure will, in most cases, cause the loss of all details above and beyond the maximum permissible signal amplitude level. It is proposed that in particular the bright parts of a scene are compressed by means of a non-linear transfer function such that the specific demands of an input signal are taken into account.

The invention relates to the method of signal reconstruction comprising a dynamic range control processing of an input image signal to generate an output image signal. The invention also relates to an imaging device for a signal reconstruction comprising a means for dynamic range control processing of an input image signal to generate an output image signal. Further the invention also relates to a computer program product.

An imaging device usually comprises an optical system for generating an image and a sensor means for transforming the optical image into an analog signal. The analog signal comprises the image information. The sensor means may either be a black/white sensor or a color sensor. Such a sensor is usually constituted by a matrix of pixels arranged in an array which may function as a CMOS-based device or as a CCD-type device. The analog signal of such a device comprises information according to the optical information as sensed by each pixel and is usually converted for further processing by an analog-to-digital converter (ADC).

A color signal may be provided in one of the standards known as the Y-UV system or the RGB-system. The luminance and color coordinates of both systems may be transformed into each other by a suitable matrix transformation. In the RGB-system the luminance may be derived from the R, G and B-components whereas in the Y-UV system the luminance is provided as the Y-component.

The analog signal is transformed into a digital signal by an analog-to-digital converter (ADC). The analog and digital information may be scaled in a certain bit range depending on the ADC. This range is referred to as the dynamic range of the image. Some prior art methods, such as the one disclosed in U.S. 2001/0005227 A1, provide a suitable imaging device capable of remarkably increasing the dynamic range of an amplification-type CMOS image sensor and of obtaining a good image from a small signal to large signal amplification and preventing the signal from being clipped.

More advantageous contemporary methods of analog-to-digital conversion of the analog to the digital signal, such as the one disclosed by WO 99/60524, attempt to increase the contrast in the resulting image without necessitating an increase in the dynamic range of the analog-to-digital converter used in converting the analog image signal into digital information. A dynamic range of images may be enhanced without increasing the range by compressing the input range of the input signal in a smaller bit range of an output range of the output signal during digital signal processing. Such compression of the input signal may be advantageously performed by any desired transfer function during digital signal processing.

However, the provision of a suitable non-linear transfer characteristic that can be used as a transfer function and is capable of compressing the input signal within a dynamic range control at the processing module causes particular problems.

For instance, the amount of dynamic range compression itself may be specified by an auto exposure unit in combination with a peakwhite detector for sensoring the peak value of a white scene of an image. This allows the amount of dynamic range compression to be determined. However, in most cases, rather arbitrary concepts have been applied subsequent to the processing of a dynamic range control. This often results in rather poor image quality during image amplification, as so far it has not been possible to specifically adapt a dynamic range control processing to an input image signal. Dynamic range control is of particular interest for scenes with a very high contrast between the dark and bright parts. Both parts may contain detailed information but, in most cases, the dark part is given priority in contemporary devices. This often results in problems as the dark parts of the scene are amplified to a level that offers sufficient visible details, whereas the bright parts in such a case exceed the maximum permissible signal amplitude and will be clipped. This will usually cause a loss of all details above and beyond the maximum level of signal amplitude. A concept which is able to provide a specific particularly suitable transfer function would be advantageous as this would allow to adapt the way of controlling the dynamic range of processing with respect to a specific quality and kind of image signal.

This is where the invention comes in, the objective of which is to specify a method and apparatus of signal reconstruction, comprising a dynamic range control processing of an input image signal to generate an output image signal based on a concept which is able to account for specific input image signal demands.

As regards the method, the object is achieved by a method as mentioned in the introduction, the method comprising the steps of:
providing the input signal;
determining an amount by:
   specifying an input range of the input signal, and
   specifying an output range of the output signal;
selecting a convex function as a non-linear transfer characteristic capable of compressing the input signal according to the amount of dynamic range control processing;
processing the input signal wherein the input signal is transferred by means of the convex function;
generating the output signal as a result of the processing.

As regards the apparatus, the object is achieved by an imaging device as mentioned in the introduction, wherein according to the invention the device comprises:
an input means for providing an input signal;
a means for determining an amount comprising:
   a means for specifying an input range of the input signal, and
   a means for specifying an output range of the output signal;
a computing means for selecting a convex function as a non-linear transfer characteristic capable of compressing the input signal according to the amount of dynamic range control processing;
a processing means for transferring the input signal by means of the convex function;
an output means for generating the output signal as received by the processing means.

Further, the invention leads to a computer program product that can be stored on a medium that can be read by a computer system, comprising a software code section which induces the computer system to execute the proposed method when the product is executed on the computer system.

The proposed concept has arisen from the desire to specify an advantageous way of controlling a signal transfer in a dynamic range by suitably processing an image signal during signal reconstruction. The invention has realized that conventionally any kind of transfer function is considered suitable to process an image signal during dynamic range control, as e.g. mentioned in WO 99/62524. However, such a general approach does not account for certain specifications, which may characterize a specific image. The main idea behind the proposed concept is to provide a transfer characteristic capable of compressing the input signal, which may also be adapted to the specific demands of an input image to be processed. According to the proposed concept, a convex function is selected as a non-linear transfer characteristic capable of compressing the input signal according to the determined amount of dynamic range control processing. The input signal is processed, wherein the input signal is transferred by means of the convex function according to the determined amount of dynamic range control processing. Thus, an output signal is generated wherein all details, particularly details of light parts as compared to dark parts, are particularly well visible. Information, that would be lost with conventional methods, is advantageously preserved, albeit with an unavoidable reduction of the modulation depth.

Such an advantage is achieved by determining the amount of dynamic range control processing by specifying at least an input range of the input signal and an output range of the output signal. Consequently, the input signal is transferred by means of the convex function according to the specific demands of an input and output signal. Therefore, the best quality for each input signal is achieved. The method may be realized according to the limits of a device used for signal reconstruction.

Further developed configurations of the invention are outlined in the dependent claims.

The input and/or output range is preferably determined by means of a peak value and/or an exposure average value taken from the signal. Such values may be determined by measuring and/or performing a histogram analysis of the signal. A luminance signal is particularly suitable as a signal.

The input signal is conveniently compressed if the peak value of the input signal exceeds the output range. It may also be desirable to compress a mere fraction of the image e.g. the bright scene fractions of an image.

Most preferably the convex function is selected according to the determined amount of dynamic range control processing. In particular, the convex function is selected depending on the input and/or output range. A convex function is generally curved at the top and therefore has at least for one value a negative curvature.

In a preferred configuration the convex function is formed by at least a first and a second part with a kneepoint as a point of intersection of the first and the second part. In this case, preferably the first part of the convex function has an average steepness exceeding that of the second part to form a convex function. The kneepoint may be defined by x- and y-coordinates, wherein the y-coordinate corresponds to the kneelevel.

The kneepoint is preferably located on the convex function at a specified kneelevel separating the first part from the second part. The first and second part of the convex function are each formed most advantageously by a linear function with a constant steepness. Such a convex function configuration allows a particularly advantageous functional adaptation with regard to a signal. The function itself is simple enough to keep computing efforts low and is adaptable to a signal in a particular convenient way. These and other preferred configurations will be described in the following.

In a first variant the convex function may be selected by varying the steepness of the second part, in particular, by simultaneously keeping the kneelevel constant.

In a second variant the convex function may be selected by varying the kneelevel of the convex function, in particular by simultaneously keeping the steepness of the second part constant.

In the preferred configuration the convex function is selected depending on the amount of dynamic range control processing function, in particular depending on the input and/or output range, wherein a combination of varying the steepness of the first variant and varying the kneelevel of the second variant is available.

A particularly preferred criterion for selecting the convex function is as follows: The varying of the steepness of the second part is preferably selected if the input range of the input signal exceeds a predetermined threshold level. Also, if a chosen kneelevel exceeds the output range the varying of the steepness of the second part is preferred.

The image signal may be any signal suitable for describing an image in contemporary imaging devices. The image signal in particular has a number of components, which may include a luminance component and/or one or more chrominance components, e.g. the image signal is a Y-UV-signal or an RGB signal. Preferably, an amount of dynamic range control processing is determined on a Y-signal, in particular a Y-signal derived from an R, G, and B-component or determined on at least one component of an R, G and B-component.

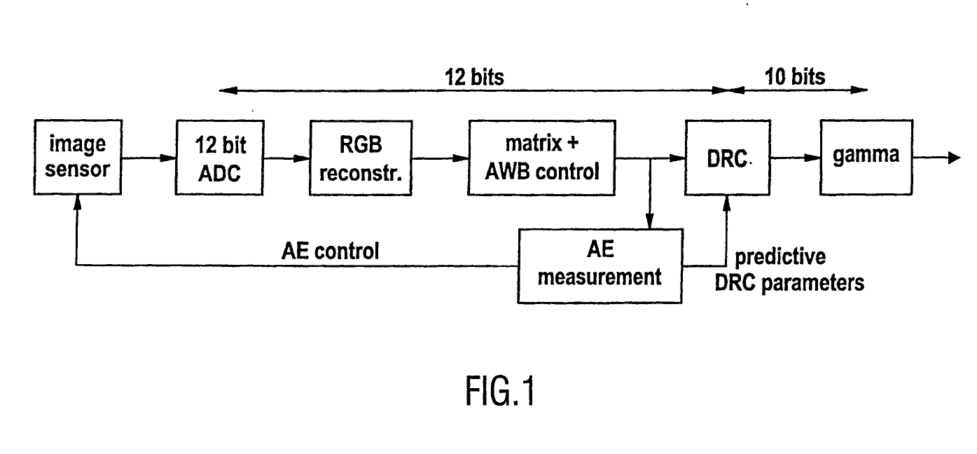

The above concept may be variously implemented in a processing chain for signal reconstruction. The input signal is preferably a digital signal, as will be explained in more detail with reference to FIG. 1 in the detailed description.

In particular, the digital signal is received from a white signal-balancing module and the output signal is provided to a gamma-control module. Thus, it is possible to advantageously apply an amount of compression range common to all signal components for dynamic range control processing and/or to process the components by means of a common convex function.

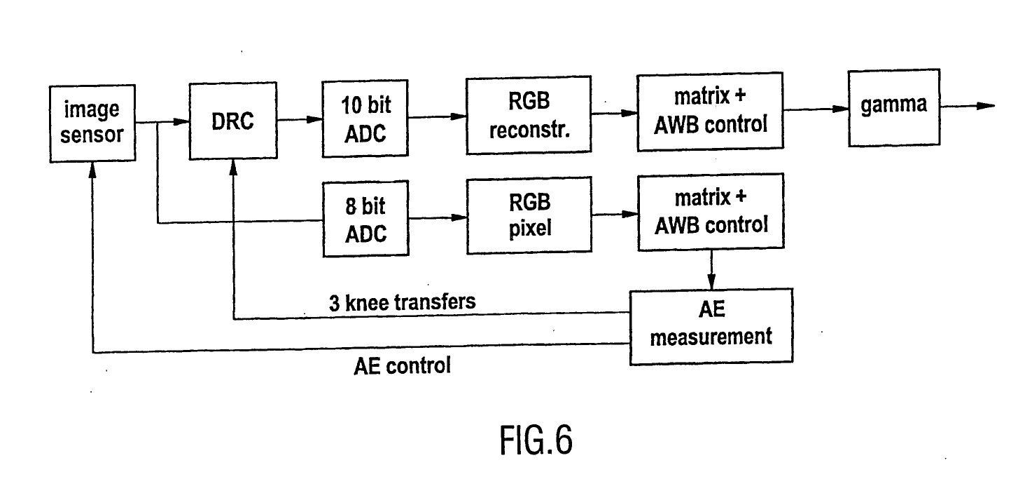

Further, the input signal may also be an analog signal, which will be explained in more detail with reference to FIG. 6 in the detailed description. In such a case the input signal is received from a sensor, in particular a sensor matrix, and the output signal is provided in particular to an analog-to-digital converter. Most preferably in such a case a specific amount of compression range is specifically applied to at least one or all of the signal components for dynamic range control processing and/or each of the components is processed by transferring the component by means of a specific convex function according to a determined amount specific of each component. Consequently, each component is treated in a separate and specific way according to the advantageous demands of each component. Each component may be used to select the steepness, and/or kneelevel and/or input range. Yet, common signals may also be selected from in particular luminance signals. Furthermore, the steepness and/or kneelevel and/or input range may also be selected according to a sensor matrix and/or a temperature value for each signal component, in particular a color component.

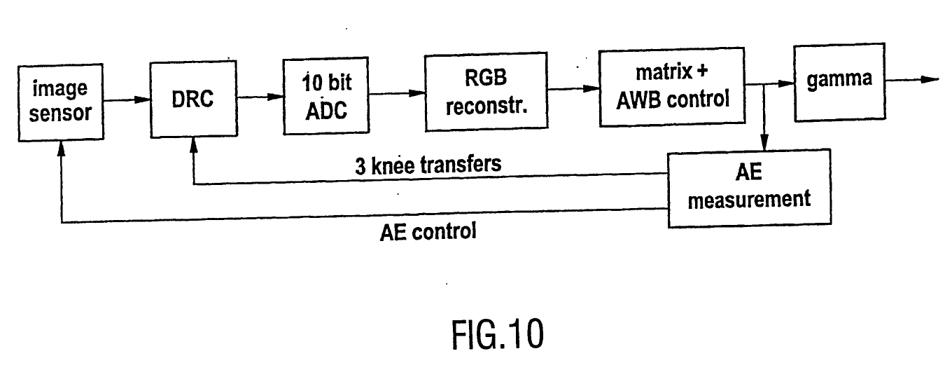

If the input signal is an analog signal in a further developed configuration the input and/or output range may also be determined from a digital signal, which will be explained in more detail with reference to FIG. 10 in the detailed description.

It is particularly preferable to provide an exposure measurement in a loop parallel to the dynamic range control processing. Also it is preferable to provide a white balance control in a loop in parallel with the dynamic range control processing. In the above further developed configuration advantageously one single parallel loop for an exposure measurement is provided.

In particular for the case of the further developed configuration it is advantageous that original data of the input signal are retrieved. As the original data are most reliable for determining the amount of dynamic range control processing, these are preferably provided to an exposure measurement and a white balance control. Preferably the original data are retrieved by means of an inverse non-linear transfer characteristic. If, however, a histogram is used for an exposure measurement, it is also possible to apply a histogram stretcher alternatively or additionally.

An exposure measurement is preferably controlled to assign the maximum output signal amplitude to a peak value of white. In particular, if an inverse non-linear transfer characteristic is used, such control is preferably provided to prevent errors at an increasing scene illumination.

As regards the computer program product, it may comprise a module for calculation of a dynamic look-up table for selection of a convex function as a non-linear transfer characteristic depending on at least one of the parameters selected from the group consisting of: peak value, exposure average value, input range, output range, and temperature value.

The computer program product may in particular comprise a module for calculating an inverse dynamic look-up table as an inverse non-linear transfer characteristic. In a further configuration, if the input signal is an analog signal, the computer program product may comprise a module for calculating a specific dynamic look-up table and a specific inverse dynamic look-up table, which is specifically adapted for at least one component of the input signal.

In summary a dynamic range control has been described which is of particular interest for scenes with a high contrast between dark and bright parts. Both kinds of parts may contain detailed information, although, in most cases, the dark part is given priority during signal reconstruction processing. In such a case the dark parts of a scene are amplified to a level that offers sufficient visible details, whereas in most prior art cases the bright parts may exceed the maximum permissible signal amplitude and will then be clipped. Such a measure will, in most cases, cause the loss of all details above and beyond the maximum permissible signal amplitude level. It is proposed that in particular the bright parts of a scene are compressed by means of a non-linear function, so that the specific demands of an input signal are taken into account. It is proposed that a scene is compressed in a preferred configuration, in particular the bright parts of a scene, by means of a non-linear transfer function. The transfer function is chosen to be a convex function, which can be selected according to the demands of the amount of dynamic range control. Such a measure allows the details in a bright scene part to be preserved, although this may also result in a reduction of the modulation depth. Still such details are not lost but are instead preserved and remain conveniently visible. In a first preferred embodiment the dynamic range control processing is performed on a digital signal subsequent to a white balance control and prior to a gamma-control of the camera. In such a case an analog-to-digital converter should provide some extra bits to enable the dynamic range control processing. In a second preferred embodiment the dynamic range control processing is performed during the early stages, i.e. “in the front” of image processing in a camera, preferably acting on the original analog signal of the image sensor. Advantageously, in such a case, an analog-to-digital converter may be applied with fewer bits than in the first preferred configuration and a digital signal is still conveniently quantified. For a proper color reproduction the convex function, as a non-linear transfer characteristic, is preferably applied to at least one or all of the color components of an image signal. In a further developed configuration the input signal is also an analog signal and the output range is determined from a digital signal. The proposed method is advantageously applied to a signal of an RGB-color signal of an image sensor. A computer program is specifically adapted via the implementation of modules to calculate specifically adapted look-up tables (LUTs).

Preferred embodiments of the invention will now be described in a detailed description with reference to the accompanying drawing. These figures of the drawing are meant to show examples to clarify the proposed concept in connection with the detailed description of a preferred embodiment and in comparison with prior art. While the considered preferred embodiments of the invention will be shown and described, it should of course be understood that various modifications and changes in form or in detail could readily be made without departing from the spirit and scope of the invention. It is therefore intended that the invention may not be delimited to the exact form and details shown and described herein nor to anything less than the whole of the invention disclosed herein and as claimed hereinafter. Further, the features described in the description, the drawings and the claims disclosing the invention, may be essential for the invention considered alone or in combination.

The drawing shows in:

FIG. 1 a first preferred embodiment of the method of signal reconstruction, wherein an automatic exposure measurement and a dynamic range control are applied to a digital signal behind an analog-to-digital converter and subsequent to a matrix module and a white balance module;

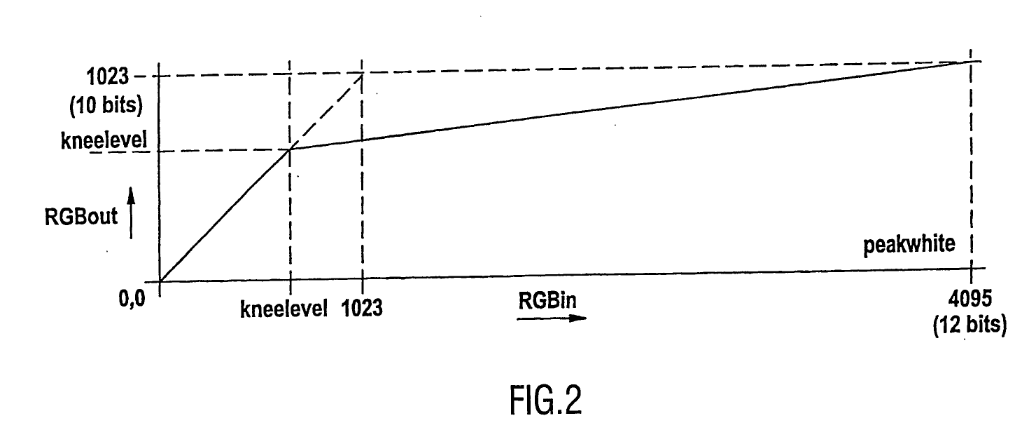

FIG. 2 a preferred scheme for selecting the convex function as a non-linear transfer characteristic;

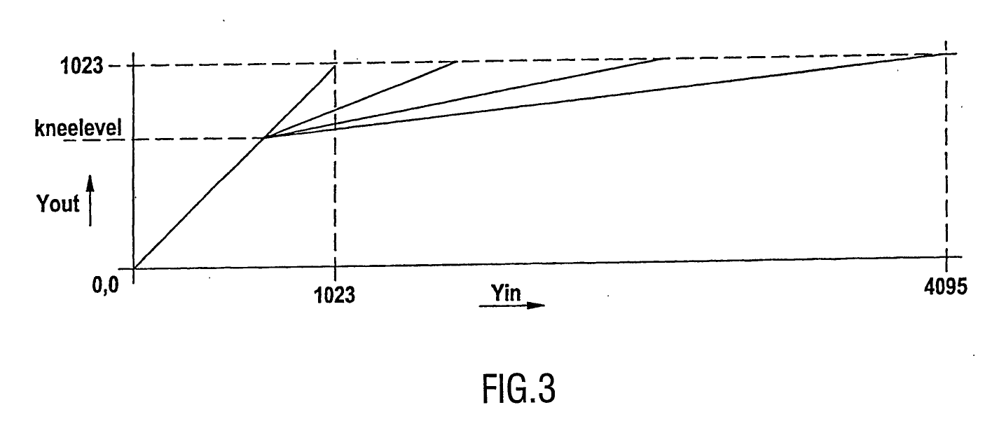

FIG. 3 a first preferred embodiment of the convex function having a fixed kneelevel and a variable compression in a second part of the convex function;

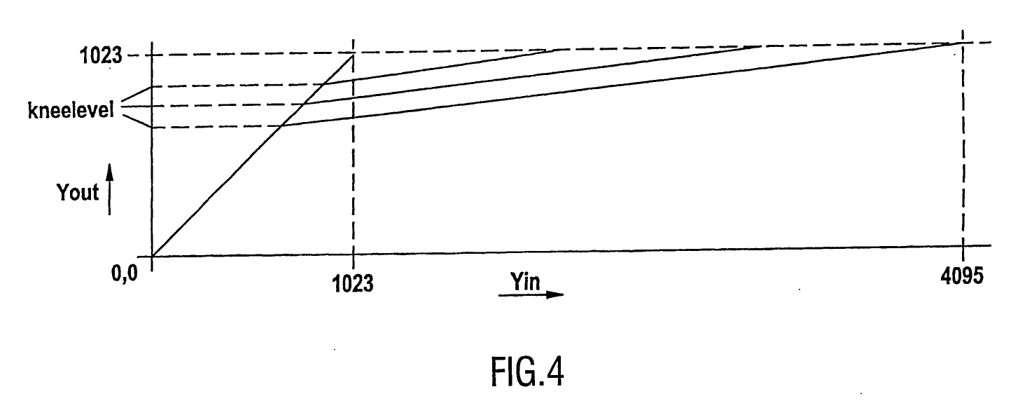

FIG. 4 a second preferred embodiment of the convex function having a fixed compression in the second part of the convex function and a variable kneelevel;

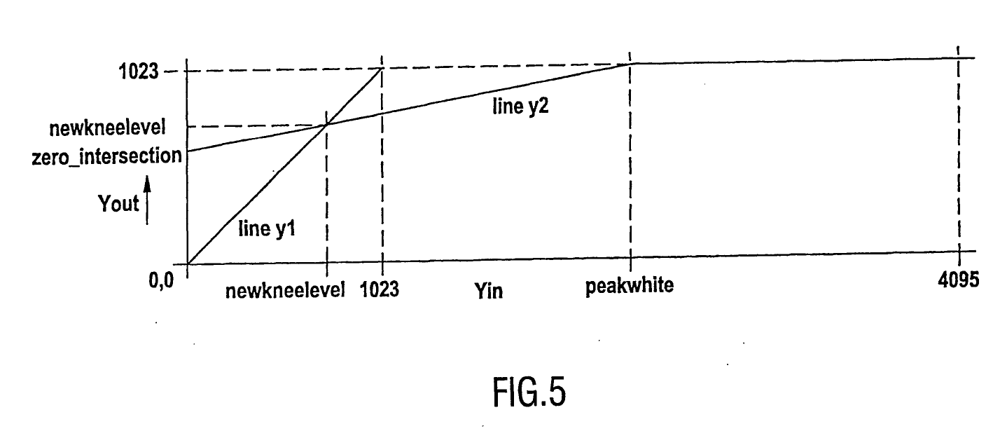

FIG. 5 an exemplifying embodiment of the convex function, wherein the parameters of a module for calculation of a kneelevel are defined;

FIG. 6 a second preferred embodiment of the method of signal reconstruction, wherein an automatic exposure control and a dynamic range control are applied to an analog signal of an image sensor before an analog-to-digital converter is applied;

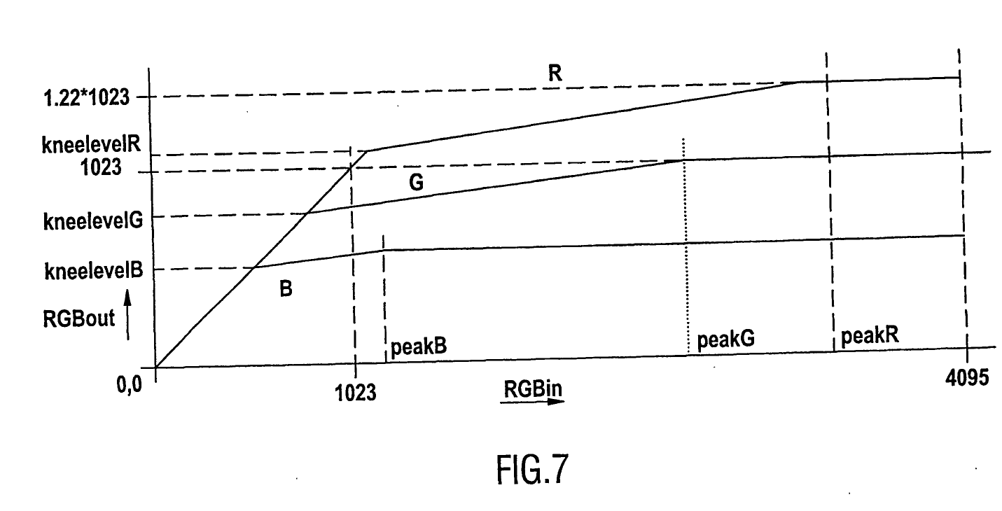

FIG. 7 a schematic view of a set of specific knee transfer functions, each of which is used respectively as a convex non-linear transfer characteristic for each of the color components of an image signal processed according to the second preferred embodiment of the method of signal reconstruction;

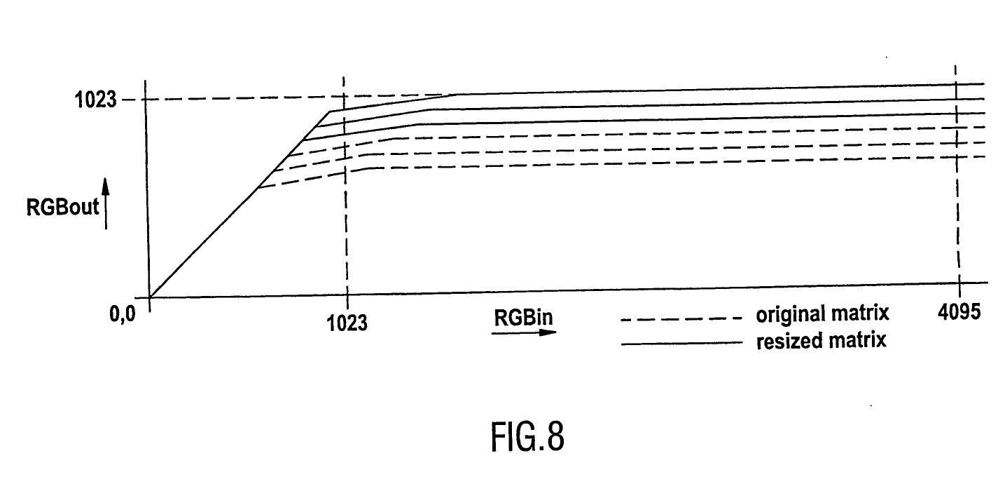

FIG. 8 calculated versions of the convex functions as have been shown in principle in FIG. 7, to be used as an adaptation of a matrix for obtaining a better quantification;

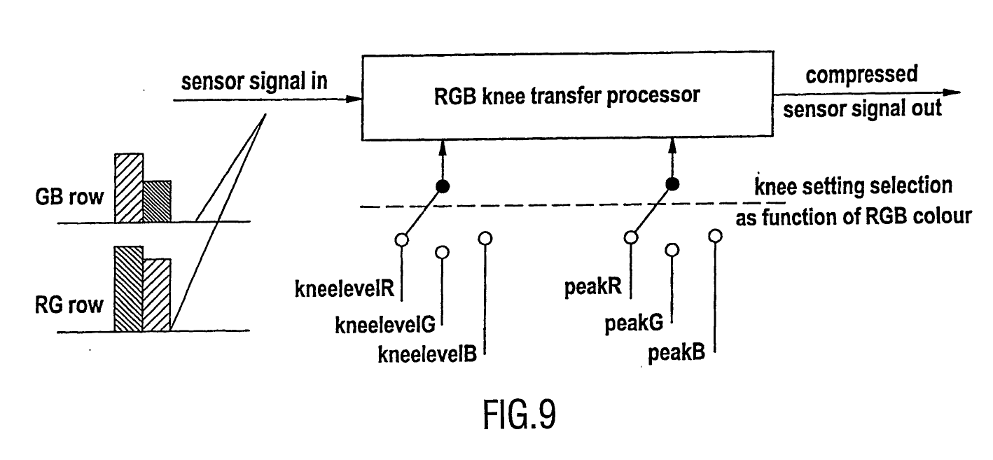

FIG. 9 a flow diagram illustrating the processing and selection of a convex function according to the second preferred embodiment with regard to the parameters “kneelevel” and “peak value”;

FIG. 10 a third preferred embodiment of the method of signal reconstruction similar to the one shown in FIGS. 6 to 8, wherein dynamic range control processing is applied to an analog signal and an automatic exposure control is applied to a digital signal;

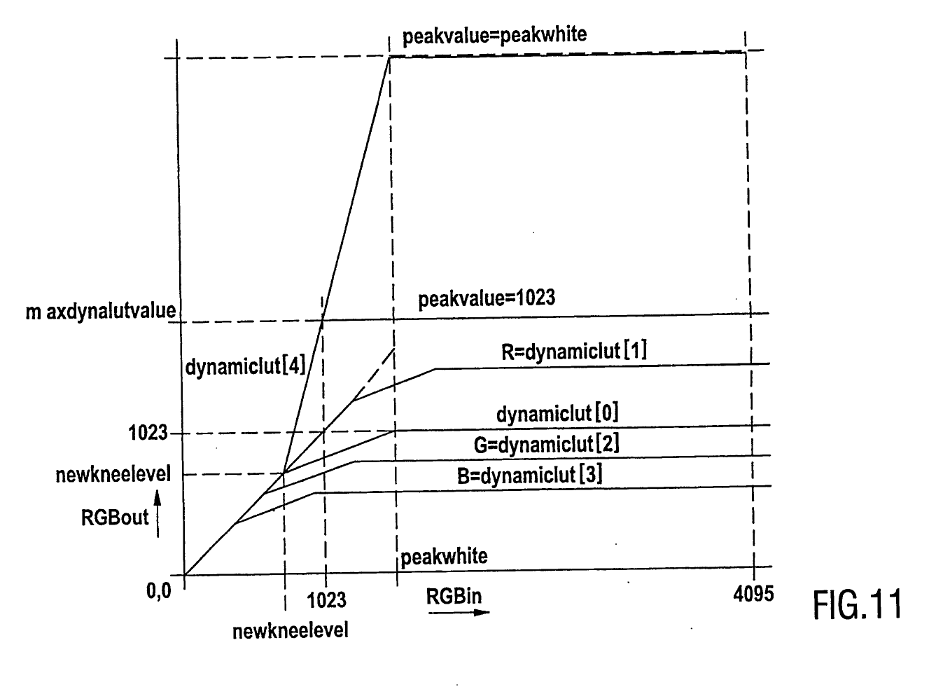

FIG. 11 a schematic view of an example of an inverse dynamic look-up table as calculated by a respective software code section;

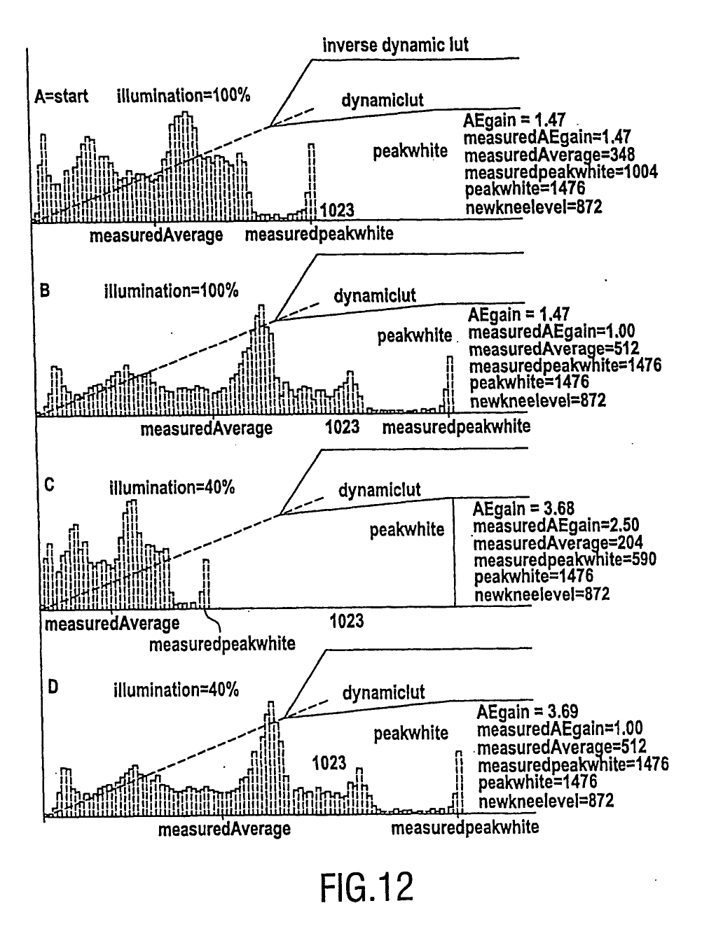

FIG. 12 some exemplifying histograms of a picture with different scene illuminations in the range from 100% to 40%;

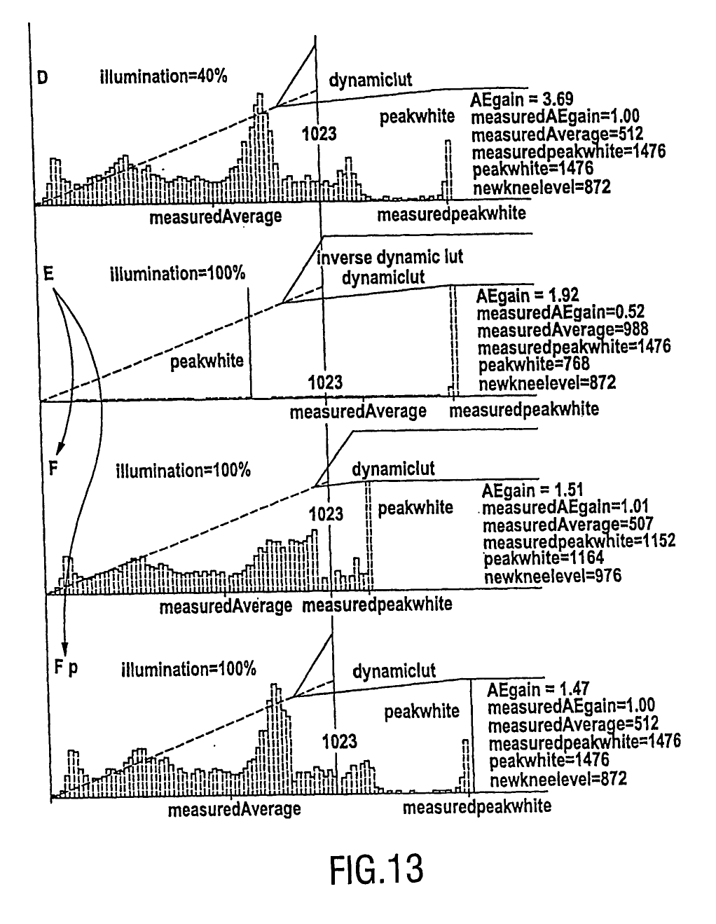

FIG. 13 like FIG. 12 for different scene illuminations in the range from 40% to 100%;

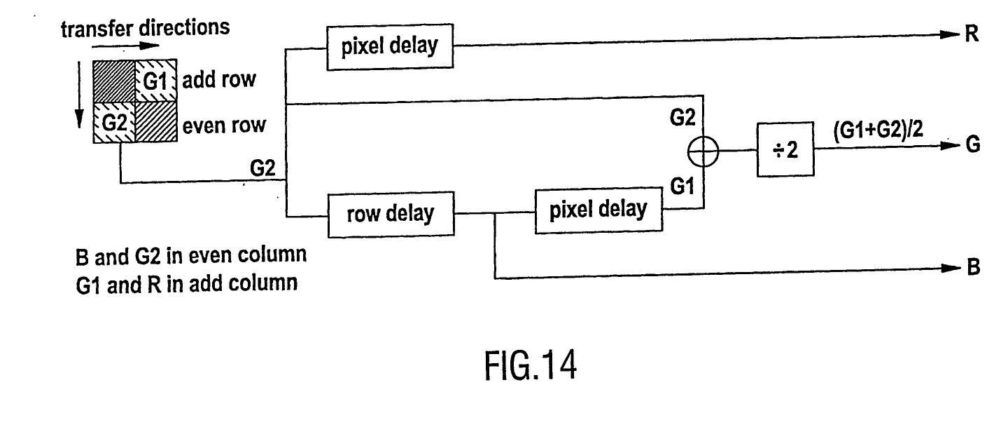

FIG. 14 a simplified RGB reconstruction in even rows at half the sensor pixel clock to be used within the second or third preferred embodiment of the method as shown in FIGS. 6 and 10 respectively;

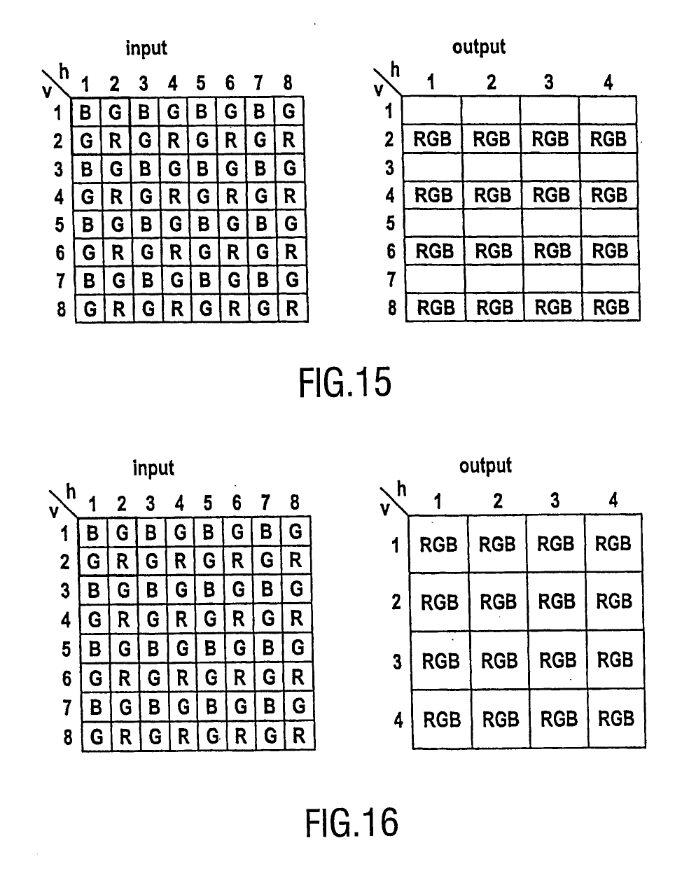

FIG. 15 a scheme of automatic exposure measurement generating a continuous RGB-measurement signal in even rows to be used for RGB reconstruction of FIG. 14;

FIG. 16 a further scheme of automatic exposure measurement generating a continuous RGB-measurement signal applicable at a quarter of the sensor clock speed.

The following detailed description accompanies the drawing and comprises the following chapters:
1. Dynamic range control subsequent to a matrix and white balance control
   1.1 Two types of transfer characteristics for a dynamic range control
2. Dynamic range control before an analog digital converter
   2.1. Dynamic range control with a parallel processing loop for measurement
   2.1.1. The influence of a matrix and white balance parameters on a knee transfer
   2.1.2 Calculation of a dynamic look-up table for an RGB-sensor signal
   2.2. Dynamic range control with an inverse dynamic look-up table for measurement
   2.2.1 A problem with increasing scene illumination

Appendix: A simplified RGB reconstruction of a dynamic range control applied to an analog sensor signal.

1. Dynamic Range Control Subsequent to a Matrix and White Balance Control.

FIG. 1 shows the block diagram of a scheme of signal reconstruction, comprising a dynamic range control (DRC) located between an AWB control (Auto White Balance) and a gamma processing.

An image sensor with an RGB Bayer color array, is followed by a 12-bit ADC (analog-to-digital converter). The 12-bit ADC is of course arbitrary. Depending on the application it can be any converter between a 10-bit and a 16-bit converter, wherein it is assumed that 2 or 3 bits are reserved for the dynamic range control.

The proposed method of signal reconstruction comprising a dynamic range control processing of an image is preferably applied with images, such as e.g. computer pictures, having a 10 to 16 bit depth for each color. On 8-bit or lower depth computer pictures it may be applied as well, although then there is the risk of visible quantification.

In the preferred embodiment a 12-bit ADC with 2 bits for dynamic range control has been selected. A 100% signal amplitude is achieved with 10 bits. This allows a maximum over-exposure of a factor of 4, which corresponds to a signal amplitude of 400% or 12 bits.

Following the 12-bit ADC a multiplexed digital RGB signal is available in the form of a row alternating RG and GB sequence due to the Bayer color array. Following the RGB reconstruction three continuous RGB signals are available, each with a 12-bit quantification.

The color correction by means of the sensor matrix and the AWB control is followed by an auto exposure (AE) measurement in a parallel loop. This AE unit determines and controls the exposure time of the image sensor and also predicts the DRC parameters. For the sake of clarity, it should be mentioned that the AE control is best executed in a closed loop, while the DRC is advantageously a predictive controller.

From the ADC to the DRC a 36-bit quantified RGB signal is applied, 12 bits for each primary color. After the DRC the RGB data consist of only 10 bits per color (30 bits for RGB), corresponding to a 100% signal amplitude. FIG. 3 exemplifies a dynamic range compression of 4 times.

In the block diagram of FIG. 1 it is assumed that the AE measurement is executed on a luminance Y-signal, of which the arbitrary RGB weights are chosen according to the color television transmission agreement: Y=0.3*R+0.59*G+0.11*B.

The RGB weights in the luminance signal are usually derived from the luminance contribution of the early CRT phosphors used in the NTSC television system. Today the luminance output of the phosphors has been greatly improved, causing a completely different luminance contribution (Y=0.22R+0.71G+0.07B), as well as another color gamut. For all video cameras of known art, including the NTSC countries such as the USA and Japan, the color gamut has been adapted to the new CRT phosphors. As a result, the old luminance weights only concern an appointment about the transmission of the television signals. Moreover, due to the matching of the camera and CRT color gamut, they do not influence the color reproduction at all.

Behind the white balance control processing the RGB signals are supposed to be equal in the case of white colors. This means that the same dynamic range transfer can be applied advantageously to each of the three RGB signals. Similarly, the same gamma-transfer can be applied. If a look-up table (LUT) is used, one single LUT is sufficient for the DRC. Look-up tables will be described in further detail below.

There are many ways of realizing the AE control and of determining the amount of dynamic compression. As neither AE control nor the measuring of the dynamic compression are main subjects of this report, one can assume that the average signal of the whole scene is used for the AE control and that a rather arbitrary peakwhite detector is used to determine the dynamic compression. In this chapter a compression of four times is assumed (4096/1024). Before the DRC this results in a maximum peakwhite amplitude of (2¹²−1)=4095. RGB input signals to the DRC larger than 4095, which can be generated simply and exclusively by the matrix and the AWB control, will be limited to a maximum output level of (2¹⁰−1)=1023. The 12-bit ADC has already limited the RGB sensor signal to a maximum value of 4095. As it is rather unlikely that the RGB reconstruction will add artifacts larger than that value, the matrix and the AWB control are the only ones left that may cause artifacts.

1.1 Two Types of Transfer Characteristics for a Dynamic Range Control.

A proper choice of a kneelevel is illustrated in FIG. 2. The kneepoint can be regarded as the point at which the dynamic compression starts. In general this is rather arbitrary and will be discussed further in this chapter.

In common practice dynamic range control (DRC) is often called knee control. Therefore, in addition to the peakwhite parameter, the DRC parameters contain the word knee, e.g. kneelevel and kneecompression. The amount of compression is defined as:
kneecompression=(maximum output level−kneelevel)/(peakwhite−kneelevel)

The maximum output level according to FIG. 2 is 1023, which corresponds to an output signal of 10 bits.

There are two types of particularly advantageous knee transfers. These have been referred to as the first variant and the second variant in the general part of this application and are referred to here as kneetype 1 and kneetype 2. The first kneetype assumes a fixed kneelevel, so the attenuation above the kneelevel will vary as a function of the amount of compression as shown in FIG. 3. When considering the performance of compressed pictures, it is very disadvantageous if steep curves of a small dynamic compression factor are used, especially because most scenes need only a relatively small amount of compression.

The second kneetype supposes a fixed attenuation and, as a consequence, a varying kneelevel, of which an example is shown in FIG. 4. From a picture performance point of view this kneetype has some advantages at small dynamic compression factors, covering most of the scenes in practice. At high compression factors, however, the first kneetype with its fixed kneelevel is more advantageous. Both types of knee transfer may be combined. Either one of them may be advantageously selected depending on the suitability of the parameter.

The combination of both kneetypes offers the best performance and has been applied to the calculation of the dynamic range control in the following software description.

{Declaration of Variables, See Also FIG. 5}

| | |
|---|---|
| peakwhite, | { peakwhite without dynamic range compression } |
| kneetype, | { kneetype 1 with fixed kneelevel, type 2 with fixed compression } |
| kneelevel, | { preferred kneelevel } |
| newkneelevel, | { really applied kneelevel } |
| refkneecompres, | { preferred amount of compression } |
| kneecompres, | { actually applied compression } |
| zerointersection | { intersection of compressed line for Yin=0 } |

```
{ Calculate newkneelevel as function of kneetype }
    if peakwhite>4095 then peakwhite=4095
    newkneelevel=1023
```

| | |
|---|---|
| if peakwhite>1023 then | { dynamic compression is desired } |
| begin | { default kneetype = 2, with a fixed kneecompression, |
| | so} |

kneecompres=refkneecompres

{ find zero_intersection (Yin=0) for line y2 for which
counts:
y2 = zero_intersection + kneecompres*newkneelevel (in
Yin direction)
for peakwhite for the y2-line counts:
1023 = zero_intersection + kneecompres*peakwhite, so}

zero_intersection=1023−(kneecompres*peakwhite)

{ find newkneelevel at the intersection of the lines y1 and
y2,
y1 = 1.0*newkneeleve
y2 = zero_intersection+kneecpmpres*newkneelevel }

```
    if (1.0−kneecompres)<>0 then { prevent division by zero }
    newkneelevel=zero_intersection/(1.0−kneecompres)
    else newkneelevel=1023
    if newkneelevel<kneelevel then { step over to kneetype=1 }
    begin
    newkneelevel=kneelevel {maintain kneelevel, find kneecompres value}
    kneecompres=(1023−newkneelevel)/(peakwhite−newkneelevel)
    end
end
```

2. Dynamic Range Control Before an ADC.

The application of a dynamic range controller before the ADC becomes necessary as the state-of-the-art IC technology is not yet able to offer an ADC with sufficient bits as shown in FIG. 1. This may be the case if the ADC has to be integrated on the (CMOS) image sensor or on the signal-processing chip. It is expected that with the further refinement of IC technology it will only be a matter of time before both options can be realized. Nevertheless, two methods of a DRC acting in advance of the ADC, i.e. in the analog signal domain, will be considered here. Both methods, just like the one described in chapter 1, will predict the amount of dynamic range compression as a function of the AE control and the detected peakwhite. The first preferred embodiment using an analog signal uses an independent, parallel measurement circuit. The second preferred embodiment using an analog signal performs the measurement via the non-linear DRC and uses an inverse knee transfer subsequent to the matrix and AWB control in order to again retrieve the ‘original’ data for AE control and peakwhite detection. The first embodiment for processing an analog signal is described in chapter 2.1. The second embodiment for processing an analog signal is described in chapter 2.2.

2.1 Dynamic Range Control with a Parallel Processing Loop for Measurement.

FIG. 6 shows a DRC block diagram with a parallel processing and AE loop, which is independent of the non-linear DRC because it uses the linear sensor signal. The amount of dynamic range control is predicted via this AE loop. Of course the AE measurement can be completely realized in the analog signal domain, or possibly on the sensor itself, just as in the case of the DRC and 10-bit ADC. Here, however, a simplified digital AE loop is shown (that can also be implemented on the sensor).

This digital measurement loop starts with an ADC of only 8 bits, which appears to be sufficient for measurement purposes and has been proven by computer simulations. The multiplexed RGB sensor signal is then transferred to three continuous RGB signals (‘RGB pixel’ in the diagram) by combining the pixels within a 2×2 array, an example of which is given in the appendix. After the simplified RGB signal reconstruction the same matrix and AWB control as in the upper and true signal path are applied. The only difference is in the 8-bit signal handling. The RGB signals are then offered to the AE measurement circuit. For the true signal path a 10-bit ADC is applied after the analog DRC. The quantification close before the gamma circuit is the same as for the block diagram of FIG. 1.

The RGB signals following the white balance control should be equal for gray or white colors. Moving backwards from the AWB control, via the matrix towards the analog DRC, it will become clear that it is very unlikely that the three RGB signals are still equal for the white color after the AWB control. This will be the case if, for example, the color temperature of the scene corresponds to 6500 K and the matrix is the unity matrix. Thus, 3 knees usually have to be provided in this first embodiment for the processing of an analog signal.

2.1.1 The Influence of a Matrix and White Balance Parameters on the Knee Transfer.

The sensor matrix uses the aₓₓ parameters as follows: It is essential that the multiplication of the white balance parameters with the sum of matrix parameters be in unity. Assuming the following sensor matrix
a11 a12 a13
a21 a22 a23
a31 a32 a33
   and the measured white balance parameters awbR and awbB are given. In such a case equal analog knee transfers in the front are only obtained if:
(a11+a12+a13)*awbR=1
(a21+a22+a23)=1
(a31+a32+a33)*awbB=1
   In such case the inverse bₓₓ matrix is defined as:
b11 b12 b13
b21 b22 b23
b31 b32 b33
   It holds that A×B=1;
   where 1 is the unity matrix.

The awbR and awbB parameters are the measured white balance parameters when an arbitrary scene color temperature is given. According to the World Gray Assumption Method (WGA) the following holds true:
awbR=totalGreen/totalRed
awbB=totalGreen/totalBlue,
   where totalRed, totalGreen and totalBlue represent the total of the RGB color amplitudes measured over the whole scene. Just as in the case of the inverse matrix, the inverse white balance parameters are also needed in order to find the knee transfer for the analog DRC in the front for each primary color. This requires a great deal of calculation power because the so-called ΣXiwb-parameters need to be calculated first, followed by the RGB-transfer curves. Abbreviations are used: Σ=sigma and X=the R, G or B primary color.)
   ΣRiwb=(1/awbR)*b11+b12+(1/awbB)*b13
   ΣGiwb=(1/awbR)*b21+b22+(1/awbB)*b23
   ΣBiwb=(1/awbR)*b31+b32+(1/awbB)*b33 [1]

FIG. 7 gives an example of three different knee transfers for the analog DRC in the front. The applied matrix is in unity and the scene color temperature is about 4000K (Kelvin). It is evident that the output signal of the red knee curve exceeds the maximum value of the 10-bit ADC by a factor of 1.22. This means that an 11-bit ADC should be applied or, in case of maintenance of the 10-bit version, that the maximum output level should be lowered to 2⁹−1=511, so that 1 bit is again available for the red or blue curve as a function of a lower or higher scene color temperature than the white of an average daylight of 6500K.

In case of a unity matrix, the inverse matrix is unity as well. The ΣXiwb-parameters are then determined by the white balance parameters only.
ΣRiwb=1/awbR
ΣGiwb=1.0
ΣBiwb=1/awbB [2]
A black body radiator of 3200K gives the following ratio for the primary colors:
R:G:B=1.45:1.00:0.37
   In order to achieve R=G=B after the white balance control, the white balance parameters have to be:
awbR=1/1.45 and awbB=1/0.37
   As a consequence:
ΣRiwb=1.45, ΣGiwb=1.0 and ΣBiwb=0.37

The maximum RGB outputs of the knee transfer will then be 1.45, 1.0 and 0.37 times the maximum output of 1023 respectively.

For a color temperature of 30,000K the following holds true:
R:G:B=0.85:1.00:1.83

Here the maximum output of the blue color after the knee transfer will be 1.83 times the maximum output of 1023. Thus, in the case of a unity matrix, the factor to increase the signal amplitude of the ADC by means of a single extra bit will be sufficient for a color temperature range varying from 3200K to 30,000K. If an extra bit is assumed for the ADC, i.e. a total of 11 bits, the maximum output value will be 2¹¹−1=2047. In practice, white balance circuits will start to limit the red and blue gain factors towards rather low (3200K) and high (30,000K) color temperatures in order to maintain something of the color sphere of the original scene. Thus, the increase of the red and blue amplitude will be somewhat smaller than 1.45 and 1.83 respectively.

The maximum output after the matrix and AWB control as shown in FIG. 6 remains, 1023, however, because the RGB-amplitudes are equaled out for white. It is also important to be aware that the knee transfer of green in FIG. 7 corresponds to the transfer of the DRC after the matrix and AWB control as described in chapter 1.

In case of a color temperature of 6500K, for which the white balance parameters awbR and awbB are in unity, a formula can be written, wherein the sum of the inverse matrix parameters determines whether the maximum ADC value of 2047 will be superseded. This specific case can be important for a possible adaptation of the matrix and will be used in the following explanation.

For a color temperature of 6500K for the ΣXiwb-parameters count:
ΣRiwb=b11+b12+b13
ΣGiwb=b21+b22+b23
ΣBiwb=b31+b32+b33 [3]

In order to remain within the 11-bit range of the ADC it may be necessary to resize the matrix. For this purpose, and using a formula, [1] the ΣXiwb-values should be calculated for the limits of the color temperature range, assumed to be 3200K and 30,000K in this case. The largest of the ΣXiwb-values should then be taken. If one of them is larger than two, it should be lowered to just below two by making a proportional adjustment to the whole matrix. This will guarantee that the maximum output value of 2047 will not be exceeded. Conversely, if for 6500K the ΣGiwb-value (formula [3]) is smaller than one, then the whole matrix should be proportionally increased in such a way that the ΣGiwb-value becomes one. This will guarantee a better quantification of the sensor signal. The first priority, however, is given to resizing the matrix as a function of the limits of the color temperature range.

Two examples of existing matrices will be given to clarify this proportional matrix adjustment.

### FIRST EXAMPLE

| Matrix 1 (an FT matrix) | | | 3200K | 6500K | 30,000K |
|---|---|---|---|---|---|
| 2.000 | −0.771 | 0.006 | ΣRiwb = 1.560 | ΣRiwb = 1.454 | ΣRiwb = |
| | | | | | 1.540 |
| −0.238 | 0.762 | −0.291 | ΣGiwb = 2.227 | ΣGiwb = 2.490 | ΣGiwb = |
| | | | | | 2.922 |
| 0.045 | −0384 | 0.915 | ΣBiwb = 1.256 | ΣBiwb = 2.066 | ΣBiwb = |
| | | | | | 3.155 |

ΣBiwb at 30,000K is much larger than 2 and will be adjusted to 1.99, resulting in the following matrix and the corresponding inverse matrix:

| | | | | | |
|---|---|---|---|---|---|
| 3.171 | 1.222 | 0.009 | 0.363 | 0.422 | 0.132 |
| −0.377 | 1.240 | −0.461 | 0.123 | 1.099 | 0.349 |
| 0.071 | −0.609 | 1.451 | 0.034 | 0.440 | 0.829 |

If the gain of the original matrix had been smaller, this would have given the same result. By re-adjusting all matrix parameters by a factor of 3.171/2.000=1.5855, the auto exposure gain will also, due to the closed AE loop, be automatically adapted by the inverse gain factor used for the matrix. If, for example, the original AE gain is 2.27 for a particular scene, it will become 3.60 after the re-adjustment of the matrix. The total gain of the AE loop for that scene will thus be maintained.

### SECOND EXAMPLE

| Matrix 2 (a CMOS matrix) | | | 3200K | 6500K | 30,000K |
|---|---|---|---|---|---|
| 1.760 | −0.599 | 0.415 | ΣRiwb = 1.010 | ΣRiwb = 0.694 | ΣRiwb = |
| | | | | | 0.539 |
| −0.460 | 1.787 | −0.130 | ΣGiwb = 0.852 | ΣGiwb = 0.781 | ΣGiwb = |
| | | | | | 0.760 |
| −0.469 | −0.496 | 2.908 | ΣBiwb = 0.441 | ΣBiwb = 0.594 | ΣBiwb = |
| | | | | | 0.851 |

None of the ΣXiwb-values exceeds the factor of two. The ΣGiwb-value at 6500K is smaller than one and will be adjusted to 1.0. This will result in the following matrix and, after an extra check, in the following ΣXiwb-values for the color temperature limits:

| | | | 3200K | 6500K | 30,000K |
|---|---|---|---|---|---|
| 1.375 | −0.468 | 0.324 | ΣRiwb = 1.293 | ΣRiwb = 0.888 | ΣRiwb = |
| | | | | | 0.670 |
| −0.359 | 1.396 | −0.103 | ΣGiwb = 0.935 | ΣGiwb = 1.000 | ΣGiwb = |
| | | | | | 0.973 |
| −0.362 | −0.388 | 2.272 | ΣBiwb = 1.503 | ΣBiwb = 0.760 | ΣBiwb = |
| | | | | | 1.089 |

The extra check clarifies that none of the ΣXiwb-values exceeds the factor of two. There are however matrices where this happens. In such a case another adjustment is required. The inverse matrix is shown below:

| | | |
|---|---|---|
| 0.759 | 0.227 | −0.098 |
| 0.207 | 0.787 | 0.006 |
| 0.163 | 0.172 | 0.424 |

FIG. 8 shows the results of the knee transfers after the adjustment of matrix 2. The gain of the original was too large. The resized matrix offers knee transfers, especially green, on or close to the maximum RGB output of 1023 and, as a consequence, a better quantification.

In FIGS. 7 and 8 kneetype=2 has been applied to the different knee transfers. A slightly better color performance occurs for kneetype=2 (with a fixed compression) than for kneetype=1 (with a fixed kneelevel). For kneetype=2 the result of the processed picture is the same as in the case of the knee processing after the matrix and AWB control, as described in chapter 1. Kneetype=1 shows a small color and amplitude deviation. Further, it is evident that neither the heaviness of the sensor matrix, nor the range of the white balance will influence the performance of this front knee processor. For implementation it is, however, important to be aware of the range needed for the three different knee transfers.

As the sensor signal is a multiplexed signal, the realization of three different knee transfers requires a selection switch that controls the knee transfer for each color. A preferred way of implementation could be achieved by switching kneelevelR(G,B) and peakR(G,B) as a function of the actual color offered by the sensor. FIG. 9 shows an example of how three different knee transfers can be realized by using a single ‘RGB knee transfer processor’ that receives the kneelevels and peak-settings via two switches in phases related to the sensor colors.

2.1.2. Calculation of the Dynamic Look-Up Tables (Dynamic Luts) for an RGB Sensor Signal.

The look-up table (lut) of the DRC, hereinafter also referred to as dynamiclut, now has to be calculated. Because this procedure also counts for the DRC as described in chapter 1, four dynamicluts are calculated.

{ Declaration of variables }

| | |
|---|---|
| EXi, | { is unity for a conventional DRC, otherwise ΣXiwb for DRC in front } |
| dynamiclut\hat{ }[k,i], | { the knee transfer for the conventional DRC (k=0) and for the front DRC |
| | (k=1 to 3), the parameter i represents the input position} |
| peakwhite, | { peakwhite without dynamic range compression } |
| kneetype, | { kneetype=0: no dynamiclut has been applied, kneetype=1 with fixed |
| | kneelevel and kneetype=2 with fixed compression } |
| newkneelevel, | { really applied kneelevel as already calculated in chapter 1.1} |
| kneecompres, | { really applied compression } |

{ Start of the calculation of the dynamicluts }

| | |
|---|---|
| if (peakwhite>1023) and (kneetype>0) then | { for peakwhite<1024 no knee transfer is needed } |
| for k=0 to 3 do | { k=0 for conventional DRC, k=1 to 3 for DRC in front } |
| begin | |
| case k of | |

| | |
|---|---|
| 0: EXi=1 | { conventional DRC } |
| 1: EXi=ERiwb | |
| 2: EXi=EGiwb | |
| 3: EXi=EBiwb | |
| end {k case} | |
| for i=0 to EXi*peakwhite do | { also peakwhite has to be multiplied with |
| | EXi } |
| begin | |

| | |
|---|---|
| if i>EXi*newkneelevel then | { compressed transfer part } |

j=EXi*newkneelevel+kneecompres*(i−EXi*newkneelevel)

| | |
|---|---|
| else j=i | { linear transfer part } |

```
    dynamiclut\hat{ }[k,i]=j
end
    for i=EXi*peakwhite+1 to 4095 do
```

| | |
|---|---|
| dynamiclut\hat{ }[k,i]=j | { above peakwhite+1 the transfer is flat } |
| end | |
| else if kneetype=0 then | |
| begin | { no dynamiclut has been applied } |

```
        for k=0 to 3 do for i=0 to 1023 do dynamiclut\hat{ }[k,i]=i
        for k=0 to 3 do for i=1024 to 4095 do dynamiclut\hat{ }[k,i]=255
    end
```

| | |
|---|---|
| | { for the analog DRC as described in chapter 2.2, |
| | the inverse lut will be calculated } |
| if peakwhite>1023 then InverseDynamicLUT | { see chapter 2.2 for this procedure } |

For k=0 the dynamiclut subsequent to the matrix and AWB control is the result, an example of which is shown in FIG. 5. As has already been explained in chapter 1, the same knee transfer is applied to the RGB signals.

For k=1 to 3, as a function of the inverse matrix and the inverse white balance parameters according to formula [1], three different knee transfer curves will result for the RGB sensor signals in the front. FIGS. 7 and 8 show two examples of those knee transfers. As the inverse sensor matrix is fixed, these analog knee transfer curves have to be recalculated every time the white balance parameters change. Only in case of an ideal unity matrix and of unity white balance parameters will the three transfer curves in the front match the curve of the dynamic compression as applied after the matrix and AWB control.

2.2 Dynamic Range Control with an Inverse Dynamic LUT for Measurement.

The second preferred embodiment of an analog DRC acting before the ADC will be considered here. The block diagram of FIG. 10 shows that the AE measurement is executed via the processing path, thus including the non-linear DRC in the front.

The three different knee transfers in the front will disturb the AE and dynamic range measurement after the matrix and the AWB control. Therefore, the luminance signal is processed first with an inverse dynamiclut before the measurement occurs. This will undo the effect of the non-linear transfers in the front and will make it possible to predict what should happen there again. Due to the inverse dynamiclut the measurement results will be the very same as those in chapters 1 and 2.1. It is, however, problematic if the scene illumination is increasing. This will be elucidated in chapter 2.2.1.

The procedure of the InverseDynamicLUT has already been mentioned in the previous chapter. After that place the last rule of the software describing the calculation of the dynamic look-up table reads:
if peakwhite>1023 then InverseDynamicLUT

The software procedure of the InverseDynamicLUT used here is one of the possible methods of calculation and has been realized as follows:

Procedure InverseDynamicLUT

{ Declaration of variables }

| | |
|---|---|
| peakvalue, | { 1023 or a value between 1023 and |
| | peakwhite } |
| maxdynalutvalue, | { the maximum value of dynamiclut\hat{ }[0,i] } |
| begin | |

```
  {calculate inverse dynamiclut}
  for i=0 to newkneelevel do dynamiclut\hat{ }[4,i]=i { linear knee
  tranfer }
  for i=newkneelevel+1 to peakvalue do
```

| | |
|---|---|
| begin | { inverse part of dynamiclut[4] } |

dynamiclut\hat{ }[4,i]:=newkneelevel+(i−newkneelevel)/kneecompres

| | |
|---|---|
| if i=peakvalue then | {after peakvalue maintain maxdynalutvalue } |

```
    maxdynalut=newkneelevel+(peakwhite−newkneelevel)/kneecompres
  end
  for i=peakvalue+1 to 4095 do
    dynamiclut\hat{ }[4,i]=maxdynalut
end {of Procedure InverseDynamicLUT}
```

FIG. 11 shows an example of an inverse dynamic look-up table, the variable dynamiclut[4] in the above software module. The conventional dynamic look-up table, the one acting before gamma as shown in FIG. 1, is represented by the variable dynamiclut[0] in the above software module. If the compression of the variable dynamiclut[0] from the variable newkneelevel to the variable ‘peakwhite’ is equal to the variable ‘kneecompres’, then the amplification in the same part of the inverse variable dynamiclut[4] amounts to 1/kneecompres. For example a compression factor of 0.25 in ‘dynamiclut[0]’ results in a gain factor of 4 in ‘dynamiclut[4]’. By using the output of ‘dynamiclut[0]’ as the input for ‘dynamiclut[4]’ a linear transfer curve up to peakwhite will again be obtained.

As the maximum luminance output value after the matrix and AWB control is limited to 1023 (the input is ‘dynamiclut[0]’), at a first glance it is sufficient to realize an inverse dynamic look-up table to 1023. As the AE control is acting in a loop the value of 1023 as the maximum luminance output could well be exceeded. Therefore, it is better to apply a ‘peakvalue’ somewhat beyond 1023, preferably between 1023 and ‘peakwhite’.

FIG. 11 shows two inverse dynamic look-up table curves, one for peakvalue=1023 and one for peakvalue=peakwhite.

It should be noticed that if a histogram has been used for the AE measurement, it is also possible to apply a histogram stretcher within the limit of the variables newkneelevel to peakwhite instead of the inverse dynamiclut as described here. The histogram stretch should be processed up to the limit of peakwhite in order to be able to recover the original histogram again.

2.1.3 A Problem with Increasing Scene Illumination.

As indicated above, the performance of using an inverse dynamic look-up table for the DRC in the front is the same as that for the method described in the chapter using a parallel measurement circuit. Before showing what may happen with a decreasing scene illumination, some variables followed by the general procedure of the auto exposure loop will first be elucidated.

```
{Declaration of variables}
    measuredpeakwhite, {the measured peakwhite value of the
    scene}
    measured Average,{ measured average of scene }
    referenceAverage, { reference average value to control to }
    measuredAEgain, { the measured auto exposure gain from scene }
    AEgain, { product of AEgain and measuredAE gain to control
    image sensor }
    peakwhite { measured peakwhite multiplied with
    measuredAEgain }
```

In the following, in 8 steps the general procedure for an AE control with the DRC in the front and an inverse dynamic look-up table is described:
1. Start with an initialization: AEgain=1.00, all dynamic look-up tables, including the inverse dynamic look-up table, are set to linear mode.
2. Via the DRC in the front, the reconstruction, the matrix and the A WB, a luminance signal is realized, the ‘measuredAverage’ and the ‘measuredpeakwhite’ values of which are measured after stretching the luminance signal by the inverse dynamic look-up table. The ‘measuredAverage’ and the ‘measuredpeakwhite’ values can also be obtained from the luminance histogram of the scene. In that case, an alternative to the inverse dynamic look-up table can be a histogram stretcher acting from the ‘newkneelevel’ value to ‘peakwhite’ If the histogram has been measured via the inverse dynamic look-up table, no histogram stretcher is of course needed.
3. The following parameters are then determined: measuredAEgain, AEgain and peakwhite.
measuredAEgain=referenceAverage/measuredAverage
   AEgain=AEgain*measuredAEgain
   The auto exposure control is a closed loop of which finally the AEgain controls the exposure time of the image sensor.
   peakwhite=measuredAEgain*measuredpeakwhite
5. In order to prevent an error in an increasing scene illumination, due to the inverse dynamic look-up table, the following rule is needed:
if peakwhite<=1023 then AEgain=measuredAEgain*1023/peakwhite
6. if peakwhite>1023 then calculate newkneelevel, see chapter 1.1.
7. if peakwhite>1023 then calculate the dynamicluts, see chapter 2.1.2.
8. Next calculate the inverse dynamic look-up table, see chapter 2.2. if peakwhite>1023 then InverseDynamicLUT
   Finally, the AE measurement restarts at step 2, and so on.

With the aid of FIG. 12 and the general procedure for an AE control as outlined above, the following explains what happens if the scene illumination decreases from about 100% to 40%. The results are drawn from an original figure, starting with an illumination of 100%. A color temperature of 6500K and a unity matrix are assumed, resulting in equal dynamic RGB look-up tables in the front.

At the initialization of step 1, the AEgain=1.00 and all look-up tables are set to linear. For all situations A to D in FIG. 12 referenceAverage=512 and kneecompres=0.25 for kneetype=2. The measured histogram of the scene is shown at the top of FIG. 12 at A=start. The horizontal axis of a luminance histogram represents the signal amplitude divided into 2ⁿ segments. With a 10-bit ADC n can be chosen between 6 and 10, i.e. 64 and 1024 segments. The vertical axis represents how many pixels of the total scene match the value of a horizontal gray-segment. Adding the counted values in all horizontal segments results in the total number of pixels of the scene. On the right hand side the measured and calculated parameters are shown as they are after execution of the program steps 2 to 8. The dynamic look-up tables shown are also obtained as they are after the execution of step 8. During step 3 the following is calculated:
measuredAEgain=512/348=1.47, AEgain=1.00*1.147=1.47 and
peakwhite=1.47*1004=1476.

In the second loop as shown in situation B of FIG. 12, steps 2 to 8 are then repeated. The RGB dynamic look-up tables have now been activated and the histogram has been measured via the inverse dynamic look-up tables. The AEgain, ‘peakwhite’ and ‘newkneelevel’ parameters are maintained. Only the measured parameters have changed due to the applied ‘AEgain’ of 1.47. If nothing happens to the scene illumination, situation B of FIG. 12 will be maintained during the following cycles of the AE measurement loop.

In situation C of FIG. 12, the scene illumination is then lowered from 100% to 40%. The measured histogram will shrink 2.5 times in amplitude (being the horizontal axis). As a consequence the ‘measured Average’ and ‘measuredpeakwhite’ values will also decrease by a factor of 2.5. In order to compensate for the illumination loss of a factor of 2.5 the ‘measuredAEgain’ will increase 2.5 times and the final ‘AEgain’ will become 1.47*2.5=3.68.

At situation D the change in illumination has been compensated by means of the AEgain and, in addition to that parameter, all others are the same as for situation B.

In conclusion, for a decreasing scene illumination the method using an inverse dynamic look-up table behaves in the same way as the method in chapter 2.1 with a parallel AE measurement.

Note that step 5 has not been activated at all because ‘peakwhite’ has been larger than 1023.

However, in case of an increase in the scene illumination, a problem could occur if, for the time being, step 5 of the general AE measurement is omitted. This will be explained by increasing the illumination of the original of a figure from 40% back to 100% again.

FIG. 13 starts with situation D, which is copied from situation D of FIG. 12.

In situation E of FIG. 13 the illumination is increased to 100%. Due to AEgain still being 3.69, and the dynamic look-up table being followed by the inverse dynamic look-up table, all luminance values above 1476 are limited (clipped) to that value. As a lot of data is clipped, a large histogram segment occurs near to value 1476 which corresponds to the measured peakwhite. The measured average has become very high as well (988). Step 2 results in the following parameters:
measuredAEgain=988/512=0.52, AEgain=3.69*0.52=1.92 and
peakwhite=0.52*1476=768.
Steps 6, 7 and 8 of the general procedure are not activated because peakwhite is not larger than 1023. This means that the previous (inverse) dynamic look-up tables will be maintained.

By omitting step 5 in the general AE procedure, the intermediate state E will finally, i.e. after already two loops, become situation F, which appears to be a stable situation. The dynamic look-up tables and, in consequence, all other parameters shown on the right side of situation F, clearly differ from the desired situation B as shown in FIG. 12. This is caused by the fact that a part of the scene data is still clipped. Peakwhite is not the desired peakwhite value, because the last segment of the histogram contains an undefined amount of clipped data. Therefore, a solution that indicates how much data has been clipped cannot be applied. The software simulations clarify that the omission of the condition that peakwhite should be larger than 1023 in step 6, 7, and 8, causes an instability of the AE control.

Of course, there may be other possible solutions as well. The one applied here adds step 5 to the general AE procedure. As previously outlined, in situation E of FIG. 13 the steps 6, 7, and 8 are not executed. Because peakwhite is smaller than 1023 step 5 will become active:
AEgain=measuredAEgain*1023/peakwhite=0.52*1023/768=0.69.

With step 5 activated all parameters in situation E are the same as if step 5 had been omitted. The only difference concerns the ‘AEgain’ which is 1.33. In the next loop the desired dynamic look-up tables have already been found and are the following loop situation Fp is illustrated in FIG. 13 with its stretched histogram. As can be seen, situation Fp is very similar to situation B in FIG. 12.

Finally the following has to be noted:

1. The use of step 5 in the loop has a very interesting advantage for the AE control. If for example a text on a white paper is measured without step 5 having been activated then the AEgain will become somewhat larger than 0.5. The signal amplitude corresponding to the white paper will become about 50%, and will thus be displayed as a gray instead of a white paper. With step 5 activated the AEgain will be about 1.0, so the white of the paper will receive a 100% signal amplitude.

2. The detection of ‘peakwhite’ should occur below the ‘whiteclip’ level of the image sensor. This procedure may be incorporated for an AE control with DRC. No time constants have been applied to the software simulations of the AE control loop.

APPENDIX: A Simplified RGB reconstruction for a DRC in front

FIG. 14 shows a simplified reconstruction for the parallel AE measurement if an analog DRC has been applied in the front. The G2 pixel is regarded as the present pixel offered by the sensor. The previous red pixel has passed through a pixel delay and will be available at the same time as G2. The G1 pixel of the previous row is matched in time with G2 via a row and a pixel delay. The G1 and G2 pixel are combined into a single green pixel. The blue pixel is also matched in time with G2 via the row delay. Three parallel RGB signals are now available when the G2 pixel is present, but only for even rows and even columns. By means of a sample and hold at half the speed of the pixel clock not shown in FIG. 14, a continuous RGB signal can be realized for even rows. For odd rows, no RGB signal is generated. As shown in FIG. 15, the AE measurement only occurs during the even rows. By means of numerous switches between delay elements as a function of a blue pixel present in an odd row, it is possible to realize a continuous RGB signal in odd rows as well. For the AE measurement this is however superfluous.

The above-mentioned simplified RGB reconstruction can be applied to CCD as well as to CMOS sensors. At the cost of extra row delays, not explained here, it will of course be possible to realize a continuous measurement signal at a quarter of the sensor clock speed. A respective continuous measurement signal is shown in FIG. 16.

1. Method of signal reconstruction comprising a dynamic range control processing of an input signal of an image to generate an output signal of the image, the method comprising the steps of:
providing the input signal;
determining an amount by:
specifying an input range of the input signal, and
specifying an output range of the output signal,
selecting a convex function as a non-linear transfer characteristic capable of compressing the input signal according to the amount of dynamic range control processing;
processing the input signal wherein the input signal is transferred by means of the convex function;
generating the output signal as a result of the processing.

2. The method according to claim 1, characterized in that at least a peak value and/or an exposure average value taken from the signal is used to determine the input range and/or the output range, in particular taken by measurement and/or histogram analysis of the signal, in particular taken from a luminance signal.

3. The method according to claim 1, characterized in that the input signal is compressed if a peak value of the input signal exceeds the output range.

4. The method as claimed in claim 1, characterized in that the input signal is compressed with regard to a mere fraction of the image.

5. The method as claimed in claim 1, characterized in that the convex function is selected depending on the input range and/or the output range.

6. The method as claimed in claim 1, characterized in that the convex function is formed by at least a first and a second part having a kneepoint as a point of intersection of the first and the second part wherein the first part of the convex function has an average steepness exceeding the average steepness of the second part.

7. The method as claimed in claim 6, characterized in that the kneepoint is located on the convex function at a specified kneelevel separating the first part and the second part.

8. The method as claimed in claim 6, characterized in that each of the first and the second part of the convex function is formed by a linear function having a constant steepness.

9. The method as claimed in claim 6, characterized in that the convex function is selected by varying the steepness of the second part, in particular by simultaneously keeping the kneelevel constant.

10. The method as claimed in claim 6, characterized in that the convex function is selected by varying the kneelevel of the convex function, in particular by simultaneously keeping the steepness of the second part constant.

11. The method as claimed in claim 6, characterized in that the convex function is selected depending on the input and/or the output range, wherein a combination of varying the steepness and varying the kneelevel is available.

12. The method as claimed in claim 6, characterized in that varying the steepness of the second part is selected if the input range of the input signal exceeds a pre-determined threshold level.

13. The method as claimed in claim 1, characterized in that the image signal comprises a number of components, in particular a luminance component and/or one or more color components.

14. The method as claimed in claim 13, characterized in that the image signal is formed by a Y-UV-signal or an RGB-signal.

15. The method as claimed in claim 1, characterized in that the amount of dynamic range control processing is determined on a Y-signal, in particular a Y-signal derived from an R-, G- and B-component or determined on at least one component of an R-, G- or B-component.

16. The method as claimed in claim 1, characterized in that the input signal is a digital signal.

17. The method as claimed in claim 16, characterized in that the digital signal is received from a white signal balancing module and, in particular, the output signal is applied to a gamma-control module.

18. The method as claimed in claim 16, characterized in that an amount of compression range is commonly applied to all components of the image signal for dynamic range control processing and/or the components are processed by means of a convex function common to all components of the image signal.

19. The method as claimed in claim 1, characterized in that the input signal is an analog signal.

20. The method as claimed in claim 1, characterized in that the input signal is received from a sensor, in particular a sensor matrix and, in particular, the output signal is applied to an analog digital converter.

21. The method as claimed in claim 1, characterized in that at least one of the components of the image signal is processed by transferring the at least one component by means of a specific convex function according to a pre-determined amount of dynamic range control processing, which has been determined specifically for the at least one component.

22. The method as claimed in claim 1, characterized in that the steepness, and/or the kneelevel and/or the input range is determined from a specific signal component, in particular a luminance signal, and is selected for all signal components.

23. The method as claimed in claim 1, characterized in that the steepness, and/or the kneelevel and/or the input range is selected according to a sensor matrix and/or a temperature value of the image for each component of the signal, in particular for a color component.

24. The method as claimed in claim 1, characterized in that the input range and/or the output range is determined from a digital signal.

25. The method as claimed in claim 1, characterized in that an exposure measurement is provided in a loop in parallel with the dynamic range control processing.

26. The method as claimed in claim 1, characterized in that a white balance control is provided in a loop in parallel with the dynamic range control processing.

27. The method as claimed in claim 25, characterized in that original data of the input signal are retrieved and the original data are provided to an exposure measurement and a white balance control.

28. The method as claimed in claim 27, characterized in that the original data of the input signal are retrieved by means of an inverse non-linear transfer characteristic.

29. The method as claimed in claim 27, characterized in that the exposure measurement is controlled to assign the maximum output signal amplitude to a peak value of white.

30. Imaging device for signal reconstruction comprising a means for dynamic range control processing of an input image signal to generate an output image signal, the image device comprising:
an input means for providing an input signal;
a means for determining an amount comprising:
a means for specifying an input range of the input signal, and
a means for specifying an output range of the output signal;
a computing means for selecting a convex function as a non-linear transfer characteristic capable of compressing the input signal according to the amount of dynamic range control processing;
a processing means for transferring the input signal by means of the convex function;
an output means for generating the output signal from the signal received by the processing means.

31. Computer program product storable on a medium readable by a computer system, comprising a software code section, which induces the computer system to execute the method as claimed in claim 1 when the product is executed on the computer system.

32. The computer program product as claimed in claim 31 comprising a module for calculation of a dynamic look-up table for selection of a convex function as a non-linear transfer characteristic depending on at least one of the parameters selected from the group consisting of: peak value, exposure average value, input range, output range and temperature value.

33. The computer program product as claimed in claim 31, characterized by a module for calculating an inverse dynamic look-up table as an inverse non-linear transfer characteristic.

34. The computer program product as claimed in claim 31, characterized by a module for calculating a dynamic look-up table and/or an inverse dynamic look-up table if the input signal is an analog signal and which is specifically adapted for at least one component of the input signal.
